(19) United States
(12) Patent Application Publication
(10) Pub. No.: US 2017/0256585 A1
(43) Pub. Date: Sep. 7, 2017

(54) SEMICONDUCTOR MEMORY DEVICE AND METHOD OF MANUFACTURING THE SAME

(71) Applicant: KABUSHIKI KAISHA TOSHIBA, Tokyo (JP)

(72) Inventor: Yoshinori KUMURA, Seoul (KR)

(73) Assignee: KABUSHIKI KAISHA TOSHIBA, Tokyo (JP)

(21) Appl. No.: 15/264,552

(22) Filed: Sep. 13, 2016

Related U.S. Application Data
(60) Provisional application No. 62/302,431, filed on Mar. 2, 2016.

(51) Int. Cl. H01L 27/24; H01L 43/10; H01L 45/00; H01L 27/22

(52) U.S. Cl. CPC H01L 27/24; H01L 27/222; H01L 43/10; H01L 45/14; H01L 45/1233

(57) ABSTRACT

According to one embodiment, a semiconductor memory device includes a substrate having resistance-change elements, a first insulating film provided on the substrate, a nonconductive barrier film provided on the first insulating film, a second insulating film provided on the barrier film, and a first interconnect and a second interconnect provided at a predetermined pitch on the substrate, the first and second interconnects being put through the first insulating film, the nonconductive barrier film and the second insulating film. Each of the first and second interconnects comprises at least two wiring layers.

### CROSS-REFERENCE TO RELATED APPLICATIONS

This application claims the benefit of U.S. Provisional Application No. 62/302,431, filed Mar. 2, 2016, the entire contents of which are incorporated herein by reference.

### FIELD

Embodiments described herein relate generally to a semiconductor memory device and a manufacturing method for a semiconductor memory device.

### BACKGROUND

In recent years, a spin-injection type magnetoresistive random access memory (MRAM) using a spin-transfer-torque (STT) write system has been proposed to promote both miniaturization of cell size and reduction in current to greatly increase capacity. In a spin-injection type MRAM, data is written by directly passing a current through an MTJ element and changing the orientation of the magnetization in a storage layer according to the direction of the current.

### BRIEF DESCRIPTION OF THE DRAWINGS

FIG. 1 is a plan view schematically illustrating a magnetoresistive memory device of a first embodiment.

FIG. 2 is a sectional view taken along line I-I′ of FIG. 1.

FIG. 3 is a sectional view taken along line II-II′ of FIG. 1.

FIG. 4 is a sectional view illustrating the structure of the memory cell section of the magnetoresistive memory device of the first embodiment.

FIGS. 5A to 5D are sectional views, each illustrating the manufacturing process of an interconnect portion which the magnetoresistive memory device of the first embodiment has.

FIGS. 6A to 6E are sectional views, each for explaining double patterning executed at the interconnect portion.

FIG. 7 is a sectional view illustrating the schematic structure of a magnetoresistive memory device of a second embodiment.

FIG. 8 is a sectional view illustrating the schematic structure of a magnetoresistive memory device of a third embodiment.

FIG. 9 is a sectional view illustrating the schematic structure of the magnetoresistive memory device of the third embodiment.

FIG. 10 is a sectional view illustrating the schematic structure of a magnetoresistive memory device of a fourth embodiment.

FIGS. 11A to 11D are sectional views, each illustrating a process of how the interconnect portion of the magnetoresistive memory device of FIG. 10 is manufactured.

FIG. 12 is a sectional view illustrating the schematic structure of a magnetoresistive memory device of a fifth embodiment.

FIG. 13 is a sectional view illustrating the schematic structure of a magnetoresistive memory device of a sixth embodiment.

FIG. 14 is a sectional view illustrating the schematic structure of the magnetoresistive memory device of the sixth embodiment.

FIG. 15 is a plan view schematically illustrating the magnetoresistive memory device of the sixth embodiment.

### DETAILED DESCRIPTION

In general, according to one embodiment, a semiconductor memory device comprising: a substrate having resistance-change elements, a first insulating film provided on the substrate; a nonconductive barrier film provided on the first insulating film; a second insulating film provided on the nonconductive barrier film; and a first interconnect and a second interconnect provided at a predetermined pitch on the substrate, the first and second interconnects being put through the first insulating film, the nonconductive barrier film and the second insulating film, and each of the first and second interconnects comprising at least two wiring layers.

Hereafter, some embodiments of the present invention will be described with reference to the drawings.

### First Embodiment

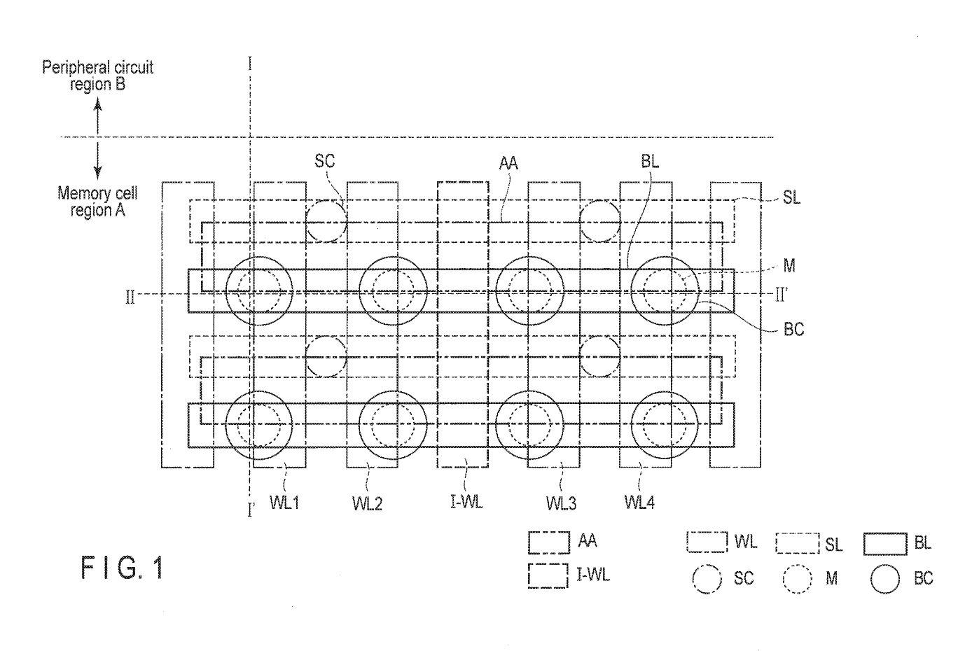

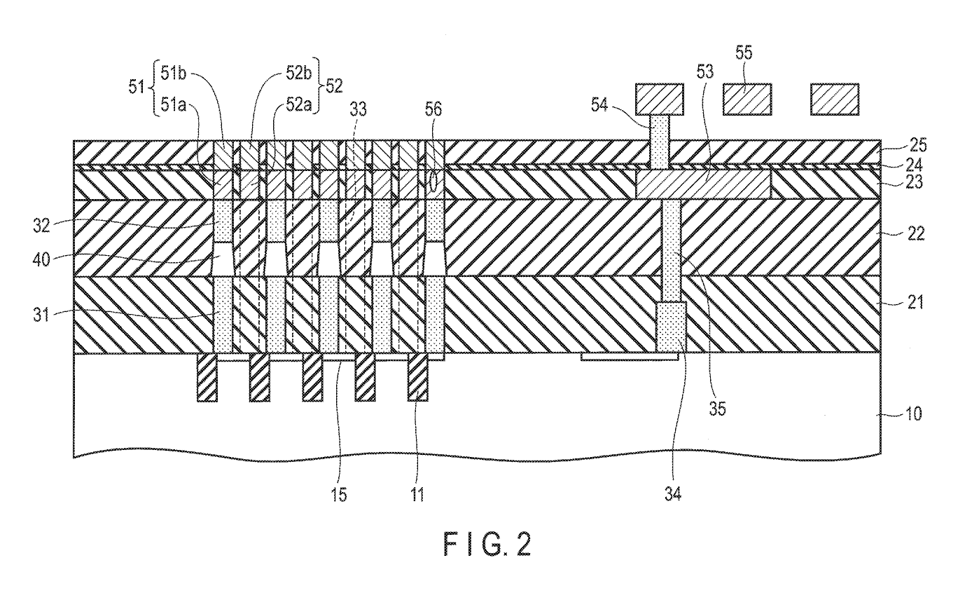

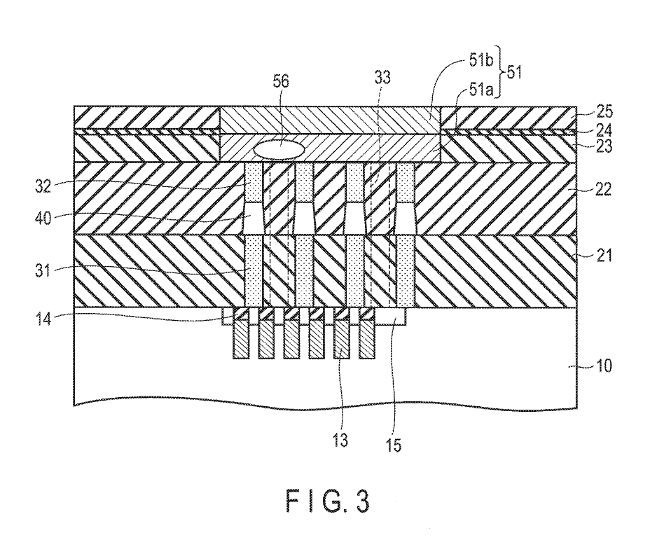

FIG. 1 is a schematic view schematically illustrating an exemplary structure of a magnetoresistive memory device of a first embodiment. FIG. 2 is a sectional view taken along line I-I′ of FIG. 1, and FIG. 3 is a sectional view taken along line II-II′ of FIG. 1.

A magnetoresistive memory device of the present embodiment is a spin-transfer-torque MRAM having magnetic tunnel junction (MTJ) element by way of the storage element. A perpendicular magnetization film is used for each of the MTJ elements. A perpendicular magnetization film is a magnetization film, in which magnetization direction (axis of easily magnetization) is oriented almost perpendicularly to a surface which the magnetization film has.

As illustrated in FIG. 1, a substrate has a memory cell region A, where MRAMs are provided, and a peripheral circuit region B, where various peripheral circuits are provided.

An MRAM of the present embodiment comprises a first select transistor, a first MTJ element M, a second select transistor, and a second MTJ element M. The first select transistor has a source, a drain, and a gate which is connected to a word line WL1. The first MTJ element M is connected to one of the source and drain of the first select transistor. The second select transistor has a source, a drain, and a gate which is connected to a word line WL2. The second MTJ element M is connected to one of the source and drain of the second select transistor. The other of the source and drain of the first select transistor is connected to the other of the source and drain of the second select transistor. That is, one memory cell of the present embodiment comprises one MTJ element (storage element) and one select transistor. Two select transistors of two adjacent memory cells, the other source/drain region is shared.

The gate of every one of the select transistors of the present embodiment has a buried gate (BG) structure. Similarly, a gate (word line I-WL) for element separation also has a BG structure.

Either the source region or drain region of the first select transistor is connected to a lower part which the first MTJ element M has. The first MTJ element M has an upper part which is connected through a plug BC to a bit line BL. The other of the source and drain regions of the first select transistor is connected through a plug SC to a source line SL.

In the present embodiment, the MTJ elements M and the plugs SC each have a circular planar pattern. However, another form may be adopted.

Either the source region or drain region of the second select transistor is connected to a lower part which the second MTJ elements M has. The second MTJ element M has an upper part which is connected through a plug BC to a bit line BL. The other of the source and drain regions of the second select transistor is connected through a plug SC to a source line SL.

Every active region AA comprises one first select transistor, one first MTJ element M, one second select transistor, and one second MTJ element M (namely, every active region comprises two memory cells). Any two adjacent active regions AA are separated by an element separation region.

Word lines WL3 and WL4 respectively correspond to the word lines WL1 and WL2. Therefore, a first select transistor, which has a source region, a drain region, and a gate region constituting a word line WL3, a first MTJ element M, which is connected to one of the source and drain regions of the first select transistor, a second select transistor, which has a source region, a drain region, and a gate region constituting a word line WL4, and a second MTJ element M, which is connected to one of the source and drain regions of the second select transistor, constitute two memory cells.

As illustrated in FIG. 2 and FIG. 3, a silicon substrate 10 has shallow trench isolation (STI) regions 11 for performing element separation. Gate electrodes 13 are formed in or on the silicon substrate 10 for constituting select transistors. The source and drain regions 15 are formed to both sides of the gate.

An interlayer insulating film 21 accumulates to cover the silicon substrate 10 and the transistors. Interlayer insulating film 21 is made to have a planar upper surface. Boron phosphorous silicate glass (BPSG), plasma tetra-ethoxysilane (P-TEOS), etc., are examples of the material of interlayer insulating film 21. The film can also take the form of a silicon oxide film produced by CVD, etc.

Contact holes for connection to the respective sources of the transistors are formed in interlayer insulating film 21, and are filled with a metal or an alloy, whereby embedded contacts 31 are formed. As the material of contacts 31, W, Ta, TiN, TaN, etc., may be used.

Each contact 31 has an MTJ element 40 as a magnetoresistive element. An interlayer insulating film 22 is accumulated to cover every MTJ element 40. Interlayer insulating film 22 is then made to have a planar upper surface. Contact holes for connection to the respective MTJ elements 40 are formed in interlayer insulating film 22. Contact holes for connection to the respective drains of the transistors are formed to extend through both interlayer insulating films 21 and 22. The contact holes are filled with a metal or an alloy, whereby contacts 32 (first contacts) and contacts (second contacts) 33 are formed.

As the material of each of contacts 32 and 33, W, Ta, Ti, TaN, TiN, etc., may be used. As the material of interlayer insulating film 22, a silicon oxide film, a silicon nitride film, BPSG, P-TEOS, etc., may be used.

An interlayer insulating film 23, such as a silicon oxide film, is formed to cover interlayer insulating film 22 and contacts 32 and 33, and is made to have a planar upper surface. Contact holes for connection to contacts 32 and 33 are formed in interlayer insulating film 23. These contact holes are filled with a metal or an alloy, whereby first wiring layers 51a are formed for the bit lines (which are constituents of respective first interconnects) and first wiring layers 52a are formed for the source lines (which are constituents of respective second interconnects). Each of wiring layers 51a and 52a may have a film thickness of several tens of nanometers, for example. Any highly conductive material, such as Cu, is desirable as the material of the interconnects.

Interlayer insulating film 23 and wiring layers 51a and 52a are covered with a barrier film 24 which functions as an etching stopper. An interlayer insulating film 25 is formed over the barrier film 24, and is made to have a planar upper surface. Interlayer insulating film 25 has contact holes for connection to wiring layers 51a and 52a. The contact holes are filled with a metal or an alloy, whereby second wiring layers 51b are formed for the bit lines (which are constituents of the respective first interconnects) and second wiring layers 52b are formed for the source lines (which are constituents of the respective second interconnects).

The bit lines 51 and the source lines 52 are thus formed. Namely, each of the bit lines 51 is formed to have a two-layer structure in which its own wiring layers 51a and 51b are placed one upon the other, and each of the source lines 52 is also formed to have a two-layer structure in which its own wiring layers 52a and 52b are placed one upon the other.

In FIG. 2 and FIG. 3, 14 denotes a protective insulating film, 34, 35 and 54 each denote a contact in the peripheral circuit region B, 53 and 55 each denote an interconnect in the peripheral circuit region B, and 56 denotes a defect generated in the wiring layers 51a.

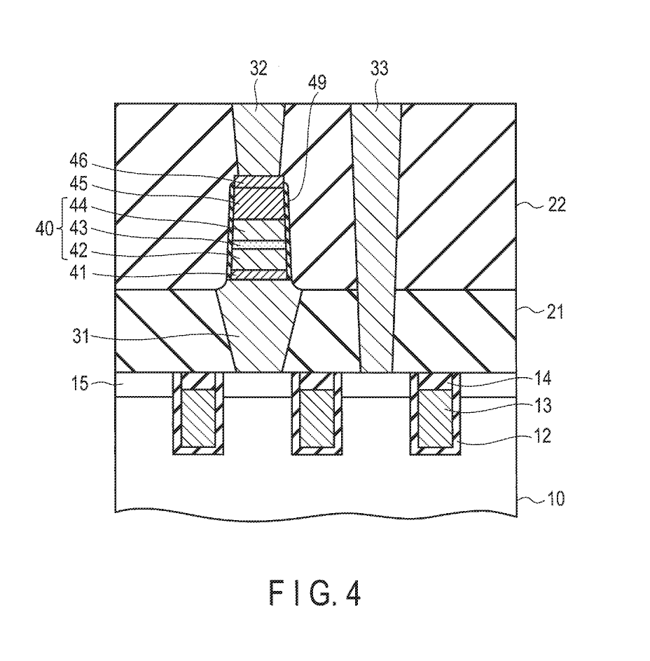

FIG. 4 is a sectional view specifically illustrating an exemplary structure of a memory cell used for a magnetoresistive memory device of the present embodiment.

The silicon substrate 10 has a surface section, on which MOS transistors are formed for switching, and an interlayer insulating film 21, such as a silicon oxide film, is formed over the silicon substrate 10 to cover the MOS transistors. The silicon substrate 10 also has grooves. Each of the transistors has an embedded-gate structure, in which a gate electrode 13 is embedded in one of the grooves of the silicon substrate 10 with the gate insulating film 12 interposed between the silicon substrate 10 and the gate electrode 13. The gate electrode 13 is halfway embedded in the groove concerned, and is covered with the protective insulating film 14, such as a silicon nitride film. Furthermore, a p-type or n-type impurity is diffused in the two opposite sides which each of the gate structures embedded in the substrate 10 has, thereby forming a source region in the one side a drain region 15 in the other.

It should be noted that the structure of a transistor section is not restricted to an embedded-gate structure. For example, a structure in which a gate insulating film is interposed between the silicon substrate 10 and gate electrodes can be adopted. Any structure can be adopted for the transistor section provided it allows the transistor section to function as a switching element.

Interlayer insulating film 21 has the contact holes for connection to the respective drains of the transistors. The contact holes are filled with conductive material, thereby forming contacts (lower electrodes [BEC]) 31. Any conductive material, including W, Ta, Ru, Ti, TaN, and TiN, may be used for contacts 31.

Each of contacts 31 is partially covered with a buffer layer 41. The buffer layer 41 includes Al, Be, Mg, Ca, Sr, Ba, Sc, Y, La, Si, Zr, Hf, W, Cr, Mo, Nb, Ti, Ta, V, etc. Moreover, their borides may also be included. Boride is not limited to binary compounds, each consisting of two elements, but it is possible to include ternary compounds, each consisting of three elements. That is, a mixture of binary compounds can be used. For example, hafnium boride (HfB), magnesium aluminum boride (MgAlB), hafnium aluminum boride (HfAlB), scandium aluminum boride (ScAlB), scandium hafnium boride (ScHfB), hafnium magnesium boride (HfMgB), etc., can be used. Furthermore, any of the above-mentioned materials may be stratified.

The use of high-melting-point metals and their borides will prevent buffer layer material from diffusing into the magnetic layer, thereby preventing deterioration of MR ratio. It should be noted that a high-melting-point metal is any material which has a higher melting point than Fe or Co. For example, Zr, Hf, W, Cr, Mo, Nb, Ti, Ta, and V may be used.

The buffer layer 41 has on it a storage layer (first magnetic layer) 42 of CoFeB and is a freely magnetized ferromagnetic layer. The storage layer 42 in turn has on it a tunnel barrier layer (nonmagnetic layer) 43 of MgO. The tunnel barrier layer 43 has on it a reference layer (second magnetic layer) 44 of CoPt and is a fixed-magnetization ferromagnetic layer. In this way, the tunnel barrier layer 43 is between the two ferromagnetic layers 42 and 44. This structure constitutes none other than the MTJ element 40.

The MTJ element 40 has on it a shift cancelling layer 45 of CoPt, CoPd, CoNi, or the like. The shift cancelling layer 45 in turn has on it a cap layer 46 of Ta, Ru, Pt, W, or the like. It should be noted that any MTJ element section including an MTJ element 40 has an upwardly projecting form. The MTJ element section has sidewalls which are covered with a sidewall protective insulating film 49 for preventing the MTJ element from being oxidized or deoxidized. The sidewall protective insulating film 49 is of, for example, SiN, Al₂O₃, or the like.

It should be noted that the buffer layer 41 is for promoting crystallization of the layer formed over it. It will therefore be possible to exclude the buffer layer 41 if sufficiently good crystals are obtained without any buffer layers. It is desirable to form the storage layer 42 with the material which has magnetic crystal anisotropy, or the material which has magnetic interface anisotropy. The same applies to the reference layer 44. Specifically, CoFeB or FeB may be used for the storage layer 42, and CoPt, CoNi, or CoPd may be used for the reference layer 44.

The sidewall insulating film 49 is a redeposited layer of etched materials of the MTJ, in which the structural material of contact 31 is included, and is mainly formed of an oxidized film of the structural material of contact 31.

Interlayer insulating film 22, which is a silicon oxide film or the like, covers the substrate including the MTJ element sections, each of which has the above structure and is formed on the substrate. Contact plugs (top electrodes [TEC]) 32 are embedded and formed in interlayer insulating film 22, and are connected to the corresponding cap layers 46 which are on the respective MTJ elements 40. Furthermore, contact plugs 33 are embedded and formed in such a manner that they extend through interlayer insulating films 21 and 22, and are connected to the respective sources of the transistors.

The bit lines connected to respective contacts 32 and the source lines connected to respective contacts 33 are formed on interlayer insulating film 22.

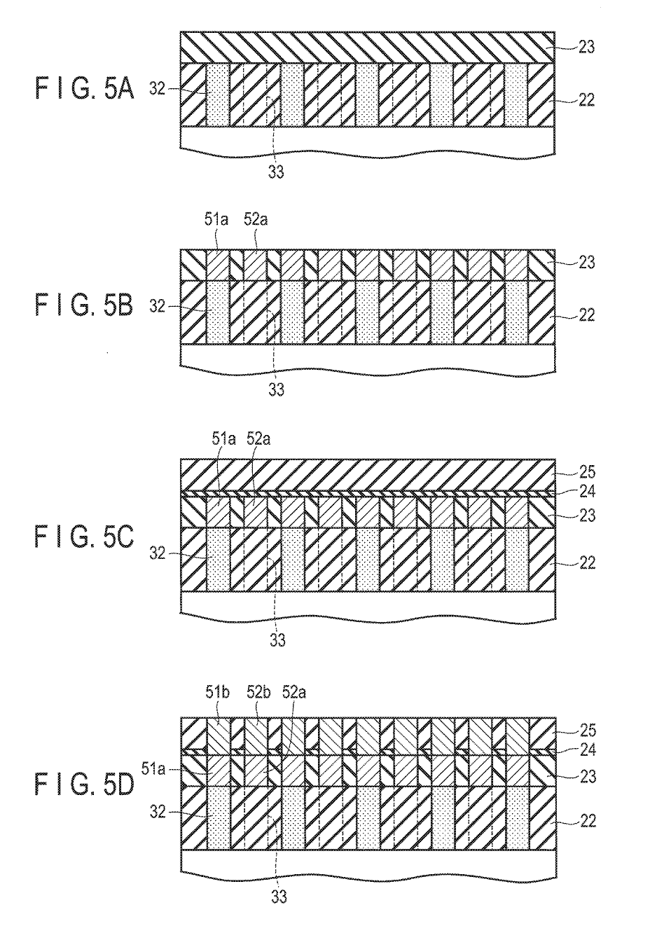

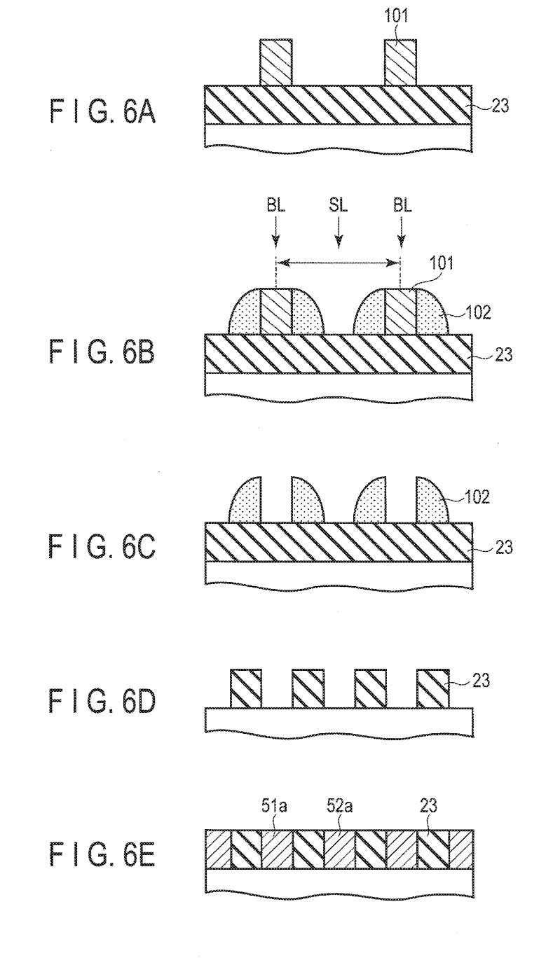

Now, the formation of an interconnect portion, which is the feature of the present embodiment, will be explained with reference to FIGS. 5A to 5D and 6A to 6E.

FIG. 5A illustrates a state where contacts 32 and 33 are embedded in interlayer insulating film 22, and interlayer insulating film 23 covers interlayer insulating film 22.

As illustrated in FIG. 5B, first wiring layers 51a of the bit lines 51 and first wiring layers 52a of the source lines are embedded in interlayer insulating film 23. Here, first wiring layers 51a of the bit lines 51 and first wiring layers 52a of the source lines 52 are formed by, for example, a double patterning process as illustrated in FIGS. 6A to 6E.

Specifically, hard masks 101 (dummy masks) are formed by resist etching after photolithography on interlayer insulating film 23, as illustrated in FIG. 6A. Subsequently, as illustrated in FIG. 6B, sidewall films (spacer films) 102 are formed to each of the hard masks 101 with the self-alignment.

Subsequently, the hard masks 101 are removed as illustrated in FIG. 6C. Subsequently, interlayer insulating film 23 is selectively etched by using the sidewall films 102 as masks, and grooves for interconnects are thus formed in interlayer insulating film 23, as illustrated in FIG. 6D. Subsequently, metal, such as Cu, is embedded in each groove and is made flat, thereby forming first wiring layers 51a and 52a, as illustrated in FIG. 6E.

It should be noted that, if the sidewall films 102 should not have a tolerance sufficient for an etching mask material, a mask material film may be formed on interlayer insulating film 23, and the hard masks 101 may be formed on the mask material film. In such a case, all that should be done is first to selectively etch the mask material film by using the sidewall films 102 as a mask, and then to selectively etch interlayer insulating film 23 by using as a mask the remaining portions of the mask material film.

First wiring layers 51a for the bit lines 51 and first wiring layers 52a for the source lines 52 are formed in this way. Subsequently, as illustrated in FIG. 5C, interlayer insulating film 23 and each of wiring layers 51a and 52a are covered with the barrier film 24 of, for example, TiN. Material such as silicon oxide is accumulated on the barrier film 24 to form interlayer insulating film 25.

Subsequently, a double patterning process is carried out again to embed and form in interlayer insulating film 25 second wiring layers 51b for the bit lines 51 and second wiring layers 52b for the source lines 52, as illustrated in FIG. 5D.

In this way, a double patterning technique is used in the present embodiment to form first wiring layers 51a and 52a in the memory cell region A. Therefore, it is possible to form the first wiring layers of the source lines to be different in width from the first wiring layers of the bit lines. As a result, resistance imbalance will occur between the source lines and the bit lines. W, TiN, Cu, Ru, Ta, etc., may be used as a material for any wiring layers. The aspect ratio (ratio of height to width) of any first wiring layer may be determined by embedding characteristics which a used material has. In the case of a Cu damascene interconnect, it is about 2. It is a material and an aspect ratio that determine the resistance of a first wiring layer. For example, when the width of an interconnect is 30 nm, the resistance obtained by summing the respective resistances of a bit line and a source line may be about 5 kΩ. In this case, the imbalance between the source line and the bit line is about 500Ω.

In addition, second wiring layers 51b and 52b in the present embodiment extend through the barrier film 24 and interlayer insulating film 25. In the memory cell region A, second wiring layers 51b are on first wiring layers 51a, and second wiring layers 52b are on first wiring layers 52a. In this way, two-layer interconnects are obtained.

Therefore, the bit lines 51 and the source lines 52 will increase in effectual aspect ratio in the present embodiment, which makes it possible to achieve a resistance half that of the conventionally value. Furthermore, the imbalance will be also half. As a result, parasitic resistance will decrease, which will cause the write current to increase. The imbalance of resistance between the bit lines 51 and the source lines 52 will improve, which will cause improvement in the signal margin. A two-layer interconnect will improve both interconnect reliability (electro migration) and yield (the avoidance of disconnection produced by a void).

Reduction in parasitic resistance and achieving a sufficient signal margin are essential in achieving a gigabit-class STT-MRAM. Transistor resistance, interconnect resistance, contact resistance, etc., are typical parasitic resistive components. The influence of interconnect resistance is expected to increase even more in the future as a result of miniaturization. Moreover, deterioration in read signal caused by imbalance in interconnect resistance between source lines and bit lines will be a problem.

Accordingly, it is very effective in achieving a gigabit-class STT-MRAM to make the bit lines and the source lines have a low resistance, as the present embodiment does.

It should be noted that each of the grooves that are etched and formed for making interconnects in each of the interlayer insulating films 23 and 25 does not necessarily have two vertical side walls. When a groove is defined by two inclined side walls, an interconnect layer embedded and formed in the groove will have two surfaces, top and bottom, which are different in width from each other. In this case, the interconnect layer should be adjusted in width based on either the width of the top surface or the width of the bottom surface. Alternatively, the interconnect layer should be adjusted in width based on the average of the width of the top surface and the width of the bottom surface.

### Second Embodiment

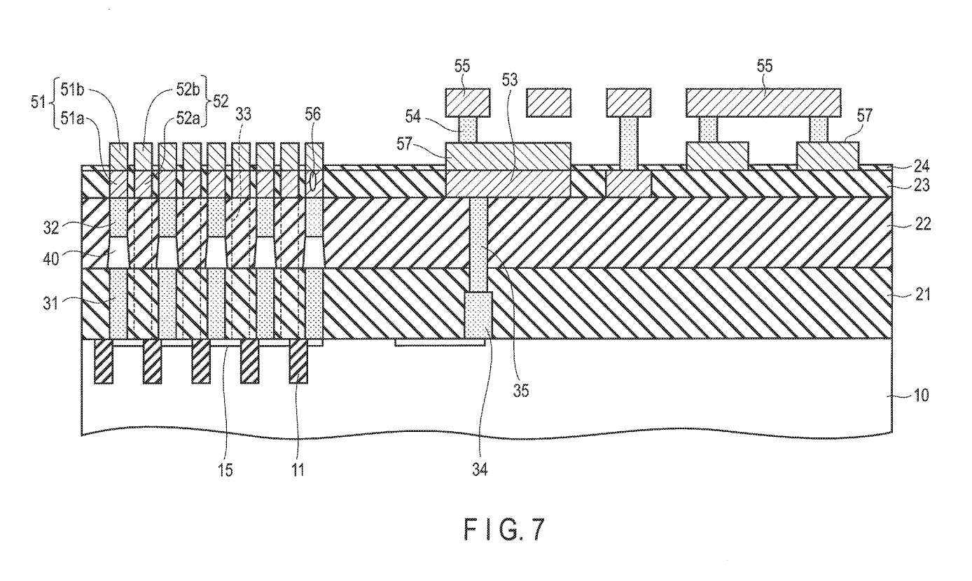

FIG. 7 is a sectional view illustrating the element structure of a magnetoresistive memory device of a second embodiment. It should be noted that FIG. 7 illustrates a cross-section taken along line I-I′ of FIG. 1, and corresponds to FIG. 2. Furthermore, those portions that are the same as those illustrated in FIG. 2 are denoted by like reference numbers, and a detailed explanation of them is omitted.

The point in which the present embodiment differs from the previously described first embodiment is that the second wiring layers are formed not only in the memory cell region A but also in the peripheral circuit region B. That is, second wiring layers 57 are on first wiring layers 53 in the peripheral circuit region B. Wiring layers 53 are formed simultaneously with first wiring layers 51a and 52a, and wiring layers 57 are formed simultaneously with second wiring layers 51b and 52b.

Such a structure has the same effect as that of the first embodiment described previously, reduces parasitic resistance in any peripheral circuit, and reduces the area of the peripheral circuit region.

### Third Embodiment

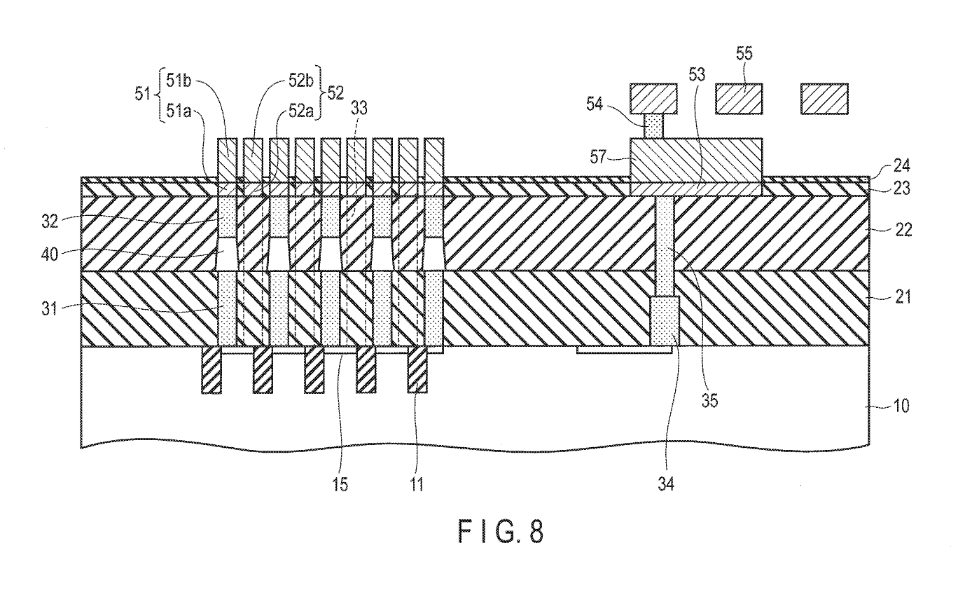

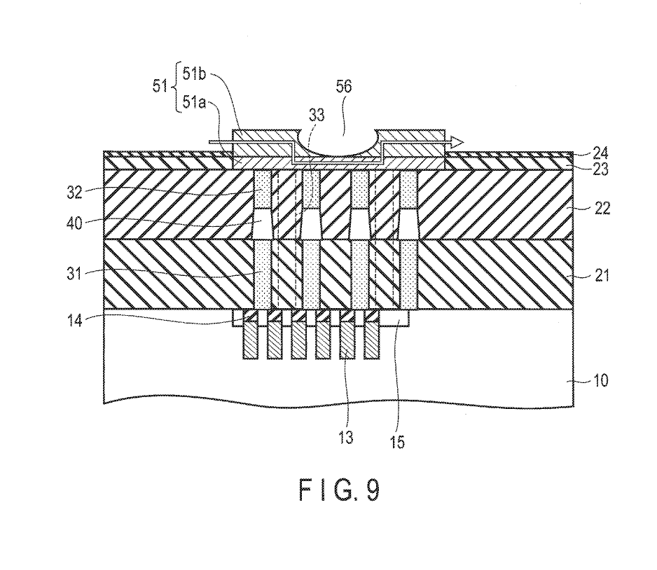

FIG. 8 and FIG. 9 are sectional views, each illustrating the element structure of a magnetoresistive memory device of a third embodiment. It should be noted that FIG. 8 corresponds to FIG. 2, and FIG. 9 corresponds to FIG. 3. Those portions that are the same as those illustrated in FIGS. 2 and 3 are denoted by like reference numbers, and a detailed explanation of them is omitted.

The point in which the present embodiment differs from the previously explained first embodiment is that the second wiring layers are made larger in aspect ratio than the first wiring layers. That is, the bit lines 51 and the source lines 52 are made to have such a structure as second wiring layers 51b and 52b are thicker than first wiring layers 51a and 52a.

First wiring layers 51a and 52a are low in aspect ratio. Therefore, they are high in reliability and yield. In contrast, second wiring layers 51b and 52b are high in aspect ratio. Therefore, they may be affected with a high possibility of embedding failure, and thus their reliability may be low. However, their resistance will be low. Altogether, the above-mentioned two-layer interconnect structure, in which the two respective layers are different from each other in aspect ratio, makes it possible to obtain an interconnect which has high reliability and low resistance.

Let us suppose that a defect 56, such as disconnection, may occur in one of second wiring layers 51b, as illustrated in FIG. 9, because of second-wiring layers 51b being high in aspect ratio. Even so, current will flow through a corresponding one of first wiring layers 51a which are low in aspect ratio. Therefore, it will hardly become a problem even if second wiring layers 51b have a risk of embedding failure.

As has been explained above, the present embodiment also achieves the same effect as that achieved with the first embodiment. Furthermore, since first wiring layers 51a and 52a are made small in aspect ratio, and since second wiring layers 51b and 52b are made large in aspect ratio, interconnects will have improved reliability and low resistance. It should be noted that some different process and some different material may be used according to circumstances for first wiring layers 51a and 52a and second wiring layers 51b and 52b.

### Fourth Embodiment

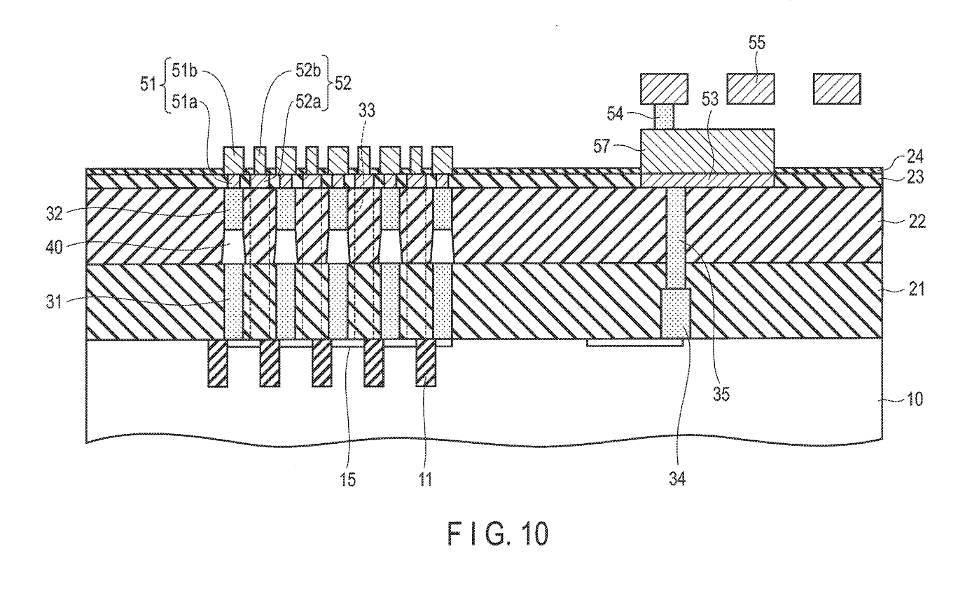

FIG. 10 is a sectional view illustrating the element structure of a magnetoresistive memory device of a fourth embodiment. It should be noted that FIG. 10 corresponds to FIG. 2. Moreover, those portions that are the same as those illustrated in FIG. 2 are denoted by like reference numbers, and a detailed explanation of them is omitted.

The point in which the present embodiment differs from the previously explained first embodiment is that the first wiring layers are made different in width from the second wiring layers.

First wiring layers 51a of the bit lines 51 are made narrow, whereas first wiring layers 52a of the source lines 52 are made wide. In contrast, second wiring layers 51b of the bit lines 51 are made wide, whereas second wiring layers 52b of the source lines 52 are made narrow. That is, the width relationship between second wiring layers 51b of the bit lines 51 and second wiring layers 52b of the source lines 52 is the opposite of the width relationship between first wiring layers 51a of the bit lines 51 and first wiring layers 52a of the source lines 52.

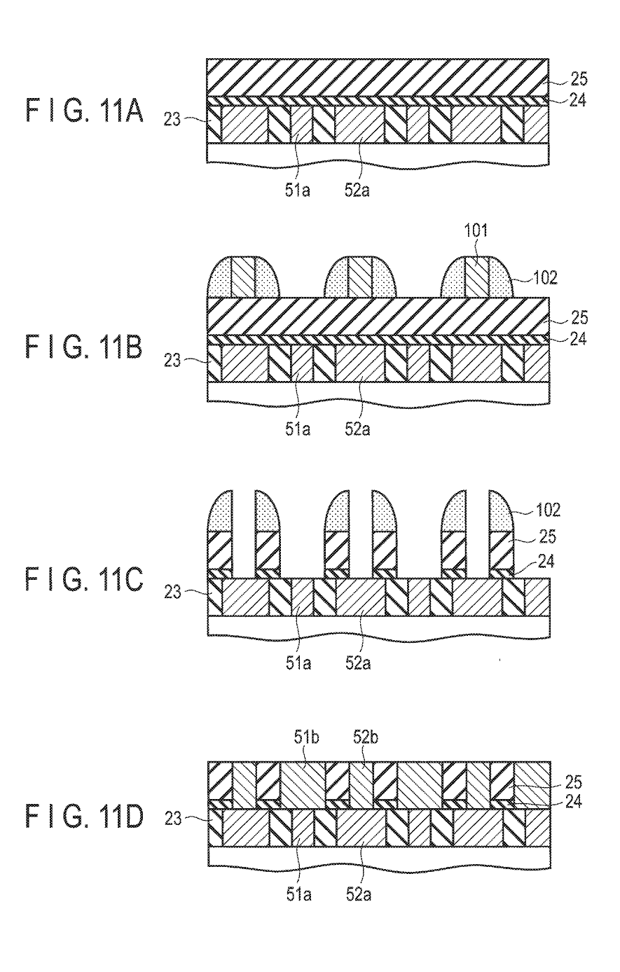

Such a pattern may be produced by the double patterning process illustrated in FIGS. 11A to 11D.

FIG. 11A illustrates a state where first wiring layers 51a and 52a, the barrier film 24, and interlayer insulating film 25 have been formed. First wiring layers 51a and 52a are formed by a double patterning process. Let us suppose that first wiring layers 51a of the bit lines 51 are formed to be narrow, and that first wiring layers 52a of the source lines 52 are formed to be wide.

In this case, hard masks 101 are formed by resist etching after photolithography on interlayer insulating film 25. Subsequently, sidewall film portions 102 are formed in a self-aligned manner at two opposite sides which each of the hard masks 101 has, as illustrated in FIG. 11B. At this moment, the sidewall film portions 102 which may be used as masks are controlled in width and thickness according to the width relationship between first wiring layers 51a and first wiring layers 52a. Specifically, in comparison with the double patterning process employed to form the first wiring layers, the hard masks 101 formed above respective first wiring layers 52a are made narrow, and the sidewall insulating film portions 102 are made thin.

Subsequently, the hard masks 101 are removed as illustrated in (FIG.) 11C. Then, the sidewall films 102 are used as masks, and the barrier film 24 and interlayer insulating film 25 are selectively etched. Grooves for interconnects are formed in the barrier film 24 and interlayer insulating film 25.

Subsequently, as illustrated in FIG. 11D, a metallic film is formed and fills the grooves. The metallic film is made flat. Second wiring layers 51b and 52b are formed.

In this way, second wiring layers 51b, each having a wide width, are formed on respective first wiring layers 51a, each having a narrow width, to constitute the bit lines 51, whereas second wiring layers 52b, each having a narrow width, are formed on respective first wiring layers 52a, each having a wide width to constitute the source lines 52. As has been explained above, the present embodiment also achieves the same effect as that achieved with the first embodiment. Furthermore, it is possible to make the overall resistance of the bit lines 51 and the overall resistance of the source lines 52 close to each other.

### Fifth Embodiment

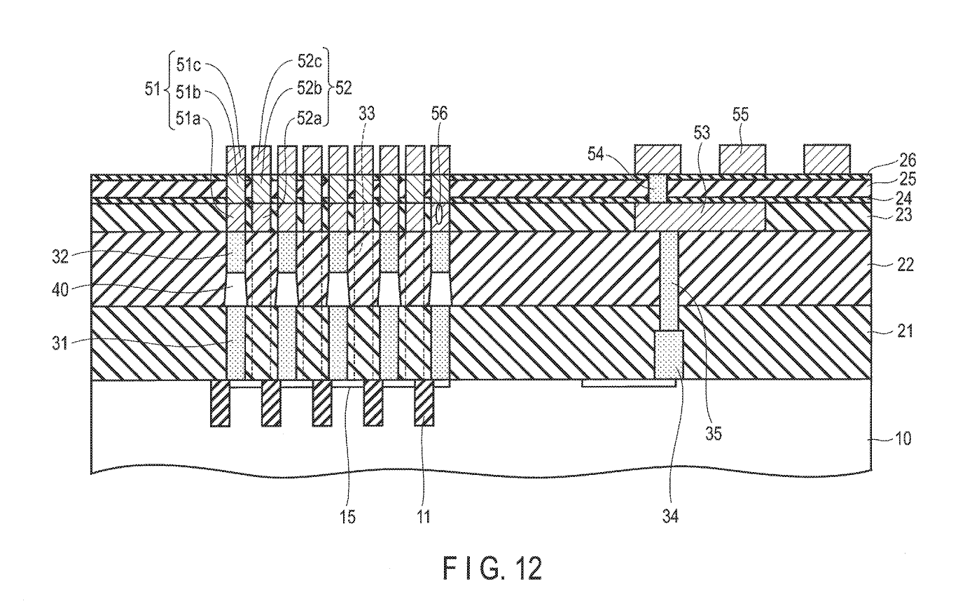

FIG. 12 is a sectional view illustrating the element structure of a magnetoresistive memory device of a fifth embodiment. It should be noted that FIG. 12 corresponds to FIG. 2. Moreover, those portions that are the same as those illustrated in FIG. 2 are denoted by like reference numbers, and a detailed explanation of them is omitted.

The point in which the present embodiment differs from the first embodiment is that any bit line has at least three layers of interconnects and that any source line also has at least three layers of interconnects. Namely, bit lines 51 are made to have a stratified structure comprising a first wiring layer 51a, a second wiring layer 51b, and a third wiring layer 51c from below upward. Similarly, source lines 52 are made to have a stratified structure comprising a first wiring layer 52a, a second wiring layer 52b, and a third wiring layer 52c from below upward.

It should be noted that 26 in the view indicates a barrier layer which functions as an etching stopper. If necessary, the bit lines 51 and the source lines 52 can be made into a multilayer.

In the present embodiment, the bit lines 51 and the source lines 52 have a three-layer structure. Accordingly, the bit lines 51 and the source lines 52 can be increased in effectual aspect ratio. Therefore, the bit lines 51 and the source lines 52 can be made to have lower resistance. Therefore, the same effect as that obtained with the first embodiment will be obtained.

### Sixth Embodiment

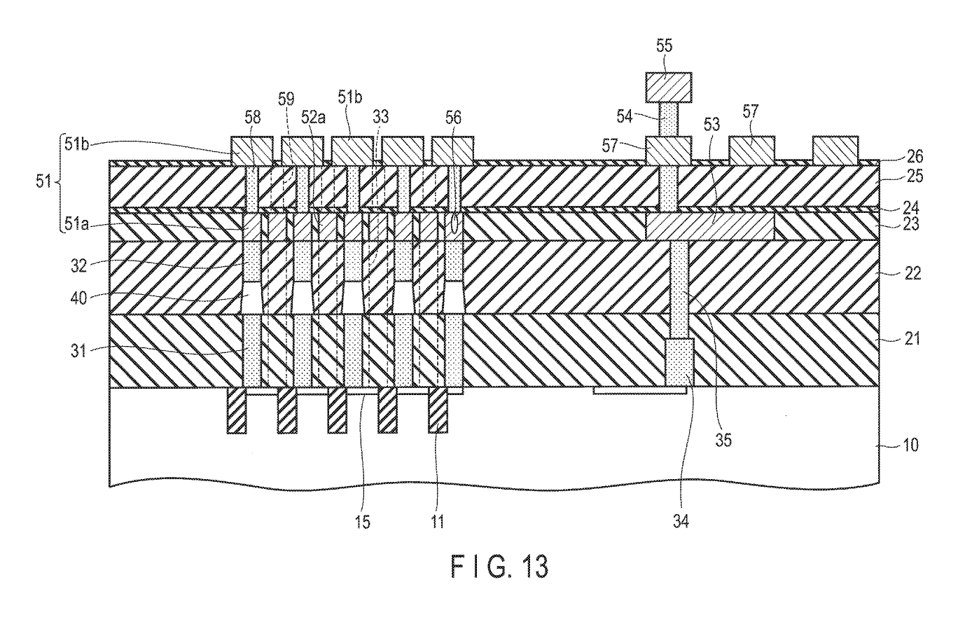

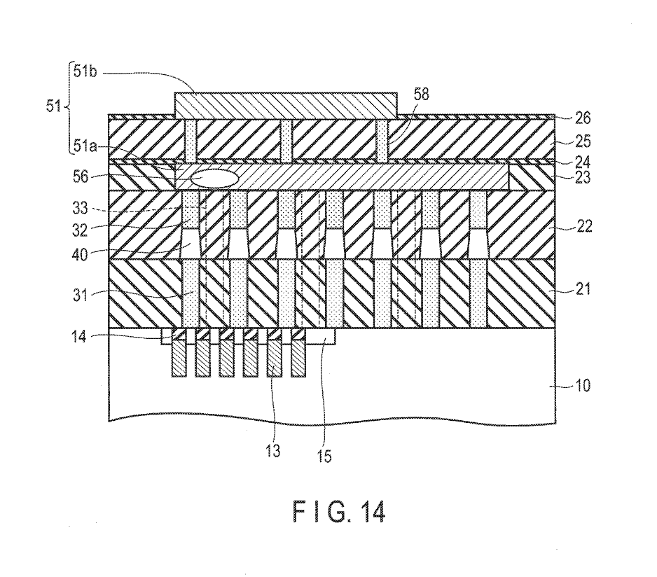

FIG. 13 and FIG. 14 are sectional views each illustrating the element structure of a magnetoresistive memory device of a sixth embodiment. It should be noted that FIG. 13 corresponds to FIG. 2 and FIG. 14 corresponds to FIG. 3. Moreover, those portions that are the same as those illustrated in FIG. 2 and FIG. 3 are denoted by like reference numbers, and a detailed explanation of them is omitted.

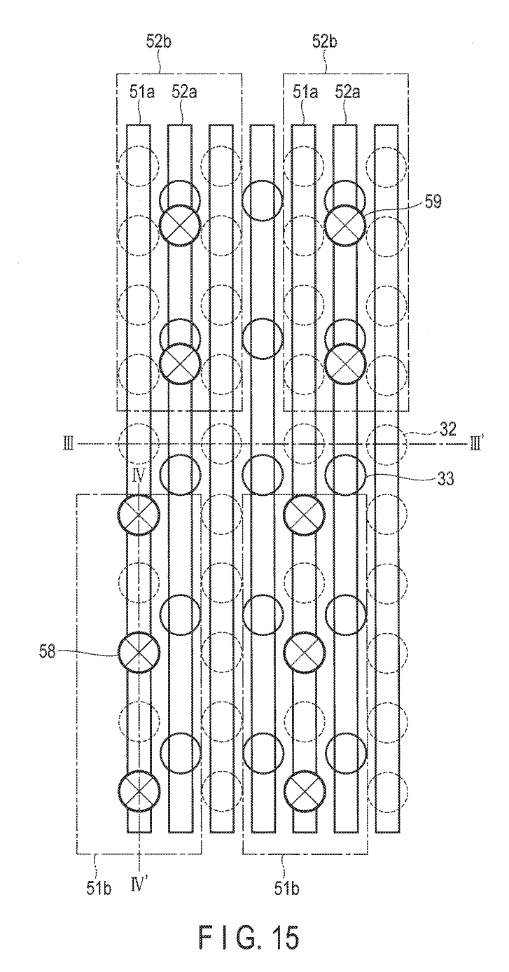

In the present embodiment, contacts, each having an upper part, are formed on first wiring layers 51a of the bit lines 51 and first wiring layers 52a of the source lines 52. Second wiring layers 51b and 52b, which follow the same design rule as peripheral circuits, are formed on the respective upper parts of the contacts. Second wiring layers 51b and 52b are wide. Accordingly, second wiring layers 51b and 52b cannot be arranged in the same pitch as first wiring layers 51a and 52a. As a result, second wiring layers 51b and 52b are made to be rectangular and are arranged as illustrated in FIG. 15. Namely, second wiring layers 51b and 52b are provided in the predetermined respective regions which are separately provided along the bit lines 51 and the source lines 52.

It should be noted that the cross-section taken along line III-III′ and the cross-section taken along line IV-IV′, both lines illustrated in FIG. 15, are respectively equivalent to FIG. 13 and FIG. 14. It should also be noted that 58 illustrated in the view representatively indicates a contact which connects one of first wiring layers 51a and a corresponding one of second wiring layers 51b for the corresponding one of the bit lines 51. Furthermore, 59 illustrated in the view representatively indicates a contact which connects one of first wiring layers 52a and a corresponding one of second wiring layers 52b for a corresponding one of the source line 52.

Such a structure makes it possible not only to obtain the same effect as that obtained with the first embodiment but also to make sufficiently wide both second wiring layers 51b of the bit lines 51 and second wiring layers 52b of the source lines 52. Therefore, the bit lines 51 and the source lines 52 will be further improved in reliability. Moreover, second wiring layers 51b and 52b can be formed simultaneously with the interconnects of the peripheral circuit area B with the same design rule as the interconnects of the peripheral circuit area B. This means that second wiring layers 51b and 52b can be formed without using any additional masks and any additional processes, which is a noticeable advantage.

(Modification)

It should be noted that the present invention is not restricted to the embodiments mentioned above.

The first and second wiring layers are not restricted to bit lines and source lines, but can be any lines alternately arranged on a substrate at a predetermined pitch.

The structure of a memory cell section is not restricted to the structure illustrated in FIG. 4, and can be changed appropriately according to the technical specification. In FIG. 4, a storage layer is arranged on the substrate side and a reference layer is arranged on the opposite side. However, this arrangement can be reversed. The memory cell is not restricted to an MTJ element, any memories being usable provided they have magnetoresistive elements. Furthermore, a memory cell is not restricted to a magnetoresistive element in which resistance changes with magnetism. It is also possible to use as a memory element a resistance-change element in which the resistance changes with some quantity other than magnetism. That is, it is possible for the memory element to constitute not only a magnetoresistive memory device but also a semiconductor memory device.

In the fourth embodiment, dummy masks are changed in width and spacer films are changed in thickness in order to perform width control of the second wiring layers of the first interconnects and the second wiring layers of the second interconnects. Instead, however, it is possible to change etching time. That is, to perform width control of the second wiring layers of the first interconnects and the second wiring layers of the second interconnects, it is merely necessary to select at least one of the following: changing the width of the dummy masks; changing the thickness of the spacer films; or changing the etching time.

The materials for the respective layers are not restricted to those that have been presented in the above explanation of the respective embodiments but may be changed appropriately according to the technical specification. Furthermore, the film thickness of each of the layers may also be changed appropriately according to the technical specification.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate including resistance-change elements;
a first insulating film provided on the substrate;
a nonconductive barrier film provided on the first insulating film;
a second insulating film provided on the nonconductive barrier film; and
a first interconnect and a second interconnect provided at a predetermined pitch on the substrate, the first and second interconnects being put through the first insulating film, the nonconductive barrier film and the second insulating film, and each of the first and second interconnects comprising at least two wiring layers.

2. The device of claim 1, wherein
the first interconnect comprises a first wiring layer and a second wiring layer,
the second interconnect comprises a first wiring layer and a second wiring layer,
the first wiring layer of the first interconnect is different in width from the first wiring layer of the second interconnect, and
the second wiring layer of the first interconnect is different in width from the second wiring layer of the second interconnect.

3. The device of claim 2, wherein
a width relationship between the second wiring layer of the first interconnect and the second wiring layer of the second interconnect is the opposite of a width relationship between the first wiring layer of the first interconnect and the first wiring layer of the second interconnect.

4. The device of claim 1, wherein
the first interconnect comprises a first wiring layer and a second wiring layer,
the second interconnect comprises a first wiring layer and a second wiring layer,
the second wiring layer of the first interconnect is higher in aspect ratio than the first wiring layer of the first interconnect, and
the second wiring layer of the second interconnect is higher in aspect ratio than the first wiring layer of the second interconnect.

5. The device of claim 1, wherein
the first interconnect comprises a first wiring layer and a second wiring layer,
the second interconnect comprises a first wiring layer and a second wiring layer,
the second wiring layers of the first interconnect and the second interconnect are alternately provided at each region along direction where the first and second interconnections are extended, and
the second wiring layers of the first interconnect and the second interconnect are wider than the first wiring layers of the first interconnect and the second interconnect.

6. The device of claim 1, further comprising
an interlayer insulating film provided on the substrate,
the first interconnect and the second interconnect are on the interlayer insulating film.

7. The device of claim 6, further comprising
first contacts and second contacts provided in the interlayer insulating film,
the first contacts connect the first interconnect and the resistance-change elements, and
the second contacts connect the second interconnect and portions on the substrate.

8. The device of claim 2, wherein
the first wiring layers of the first interconnect and the second interconnect are different in material from the second wiring layers of the first interconnect and the second interconnect.

9. The device of claim 1, wherein
each of the resistance-change elements includes a first magnetic layer having a variable magnetization direction, a second magnetic layer having an invariable magnetization direction, and a nonmagnetic layer between the first and second magnetic layers.

10. A semiconductor memory device comprising:
a substrate including a memory cell region and a peripheral circuit region, and having portions on the substrate;
resistance-change elements matrically arranged in the memory cell region of the substrate, each having one end;
an interlayer insulating film provided on the memory cell region and the peripheral circuit region and covering the resistance-change elements;
bit line contacts provided in the interlayer insulating film in contact with the one ends of the resistance-change elements;
bit lines provided on the interlayer insulating film and connecting some of the bit line contacts;
source line contacts provided in the interlayer insulating film in contact with the portions on the substrate; and
source lines provided on the interlayer insulating film and connecting some of the source line contacts,
wherein,
the bit lines alternate with the source lines at regular intervals, and
the bit lines and the source lines each comprise at least first wiring layers and second wiring layers.

11. The device of claim 10, wherein
a width relationship between the second wiring layers of the bit lines and the second wiring layers of the source lines is the opposite of a width relationship between the first wiring layers of the bit lines and the first wiring layer of the source lines.

12. The device of claim 10, wherein
in any one of the bit lines and the source lines, the second wiring layer and any succeeding layers are higher than the first wiring layer in aspect ratio.

13. The device of claim 10, wherein
the second wiring layers of the bit lines and the second wiring layer of the source lines are alternately provided at each region along direction where the bit lines and source lines are extended, and
the second wiring layers of the bit lines and the second wiring layers of the source lines are wider than the first wiring layers of the bit lines and the first wiring layers of the source lines.

14. The device of claim 10, wherein
the first wiring layers of the bit lines and the first wiring layers of the source lines are different in material from the second wiring layers of the bit lines and the second wiring layers of the source lines.

15. The device of claim 10, further comprising
peripheral circuit interconnects provided on the interlayer insulating film within the peripheral circuit region,
the peripheral circuit interconnects comprising at least two wiring layers.

16. The device of claim 10, wherein
each of the resistance-change elements includes a first magnetic layer having a variable magnetization direction, a second magnetic layer having an invariable magnetization direction, and a nonmagnetic layer between the first and second magnetic layers.

17. A semiconductor memory device manufacturing method comprising:
alternately forming first wiring layers of first interconnects and first wiring layers of second interconnects at a predetermined pitch on a substrate having resistance-change elements;
forming second wiring layers of the first interconnects on the respective first wiring layers of the first interconnects, and forming second wiring layers of the second interconnects on the respective first wiring layers of the second interconnects, after having determined a width of each of the second wiring layers of the first interconnects and the second wiring layers of the second interconnects on the basis of a width of each of the first wiring layers of the first interconnects and first wiring layers of the second interconnects.

18. The device of claim 17, wherein
a width relationship between the second wiring layers of the first interconnects and the second wiring layers of the second interconnects is made to be the opposite of a width relationship between the first wiring layers of the first interconnects and the first wiring layers of the second interconnects upon the first wiring layers of the first interconnects being different in width from the first wiring layers of the second interconnects.

19. The device of claim 17, wherein
the first interconnects and the second interconnects are formed by first forming first films having sides, second forming second films on the sides of the first films, third eliminating the first films, and fourth performing selective etching by using the second films as masks.

20. The device of claim 1, wherein
the first interconnect comprises a first wiring layer and a second wiring layer,
the second interconnect comprises a first wiring layer and a second wiring layer,
the first wiring layers of the first interconnect and the second interconnect are contact with the first insulating film, and the second wiring layers of the first interconnect and the second interconnect are contact with the second insulating film and the nonconductive barrier film.
